(19) United States
(12) Patent Application Publication
(10) Pub. No.: US 2004/0203252 A1
(43) Pub. Date: Oct. 14, 2004

(54) CMP slurry for nitride and CMP method using the same

(76) Inventor: Hyung Soon Park, Icheon-si (KR)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/738,184

(22) Filed: Dec. 17, 2003

(30) Foreign Application Priority Data
Dec. 30, 2002 (KR) 2002-86759

(51) Int. Cl. H01L 21/02

(52) U.S. Cl. 438/759; 438/758; 252/79.1; 252/79.2

(57) ABSTRACT

Disclosed is a CMP slurry for nitride having a low selectivity to oxide. More specifically, a CMP slurry for nitride is disclosed which has a high selectivity to nitride by regulating a weight content of an abrasive and by varying a pH of the slurry in order to prevent the oxide from being polished faster than the nitride. As a result, a semiconductor device of high density and high integration can be manufactured.

### BACKGROUND

1. Technical Field

A slurry used in a chemical mechanical polishing (hereinafter “CMP”) process is disclosed which is used in the manufacture of semiconductors. More specifically, a CMP slurry, that is used for polishing silicon nitride films such as SiN or SiON films, is disclosed, and a CMP method using the CMP slurry is also disclosed.

2. Description of the Related Art

Recently, much interest has been focused on a method for forming fine patterns in a semiconductor manufacturing processes. Accordingly, there are strong demands for technology of planarizing unevenness on chip and wafer surface widely.

The CMP process is one of the planarization technologies employed with lithography processes in the manufacturing of semiconductor devices. IBM developed the CMP process in late 1980's by combining a chemical removing process and a mechanical polishing process.

As semiconductors are further miniaturized in the form of high density and multi-layer structures, current CMP processes adjust the polishing speed of the wafer and employ chemical additives in the slurry to perform planarization on specific areas of the wafer. These features cannot be achieved with etchback processes.

In greater detail, a removable material is removed with a chemical material having high reactivity and a processed material of a CMP slurry and the surface of the wafer is mechanically removed by using a ultra-fine abrasive at the same time. In a CMP process, a liquid phase slurry is injected between the surface of the wafer and a rotating elastic pad in the CMP process.

The CMP process is essential to achieve a high density and high integration of semiconductor memories over 64 M and non-memory semiconductors over 250 MHz.

One generally-used CMP slurry is an oxide CMP slurry. An oxide film is polished at least twice as fast as a nitride film using this slurry. Therefore, the oxide film is polished by using the nitride film as a stop layer. The oxide CMP slurry has a nitride film/oxide film polishing selectivity of below 0.5.

However, when the nitride film is polished using the oxide CMP slurry in a Damascene metal gate process, the oxide film has a higher polishing speed than the nitride film, and as a result, a dishing phenomenon occurs in the oxide film which is used as an interlayer dielectric layer. The oxide film deteriorates in a succeeding photolithography or etching processes which makes it impossible to form a suitable barrier nitride film using to the CMP process.

Consequently, the oxide CMP slurry cannot be used to polish nitride films deposited on oxide film patterns.

### SUMMARY OF THE DISCLOSURE

Accordingly, a CMP slurry for nitride having a high polishing selectivity to nitride is disclosed, and a semiconductor device manufactured according to a CMP process using the slurry is also disclosed.

### BRIEF DESCRIPTION OF THE DRAWINGS

The disclosed CMP slurry for nitride will be described in conjunction with the following figures wherein:

FIG. 1 illustrates, graphically, a nitride film/oxide film polishing selectivity by pH variations of the slurry;

FIG. 2 illustrates, graphically, a nitride film/oxide film polishing speed by a weight ratio of the abrasive;

FIG. 3 illustrates, graphically, a nitride film/oxide film polishing selectivity by a weight ratio of the abrasive; and

FIG. 4 illustrates, graphically, a nitride film/oxide film polishing selectivity by pH variations of the slurry.

### DETAILED DESCRIPTION OF THE PRESENTLY PREFERRED EMBODIMENTS

A CMP slurry for nitride films is disclosed that has a high polishing selectivity to nitride by maintaining pH as acidic using a pH control agent and optionally by regulating a weight content of an abrasive.

Also, a process for performing a CMP process using the disclosed CMP slurry is disclosed.

A semiconductor device manufactured according to the disclosed CMP process is disclosed.

A CMP slurry for nitride has a pH ranging from about 1 to about 5 by adding a pH control agent. If necessary, the CMP slurry for nitride comprises an abrasive in an amount of below about 24 wt % based on the gross weight of the slurry in order to have a high polishing selectivity to nitride.

The disclosed slurry is acidic while the conventional slurry for oxide is alkaline. The nitride/oxide polishing selectivity of the disclosed slurry can be regulated by regulating the pH to be acidic without using an abrasive. However, an abrasive can be added depending on kinds of lower films in order to improve a polishing selectivity or an etching speed. The abrasive is present in an amount ranging from about 0 to about 24 wt % based on the gross weight of the slurry, preferably, from about 0.1 to about 24 wt %, and more preferably, from about 2 to about 20 wt %. If the abrasive is present in the amount of less than 0.1 wt %, a polishing speed does not reach a predetermined level. If the abrasive is present in the amount of more than 24 wt %, a defect such as a scratch is generated due to a mechanical factor, which results in increase of slurry prime cost.

The abrasive added to the slurry is a general abrasive. For example, any of the abrasive containing SiO₂, Al₂O₃, ZrO₂, CeO₂, MnO₂ and mixtures thereof can be used. SiO₂ which is abrasive for oxide film can be preferably used. However, when lower films are vulnerable to scratch, the polishing selectivity can be regulated by varying the pH without adding an abrasive.

A grain size of the abrasive preferably ranges from about 100 nm to 500 nm. If the grain size is below 100 nm, the polishing speed is degraded. If the grain size is over 500 nm, dispersion is difficult, which causes scratch.

The pH control agent is phosphoric acid, nitric acid, fluoric acid, isopropyl alcohol and mixtures thereof. Preferably, a phosphoric acid is singly used, a mixture of nitric acid and fluoric acid is used and a mixture of fluoric acid and isopropyl alcohol is used.

When a strong acid as the pH control agent is added to the slurry, the pH of the slurry ranges from about 1 to about 5, preferably from 1 to 3, more preferably from I to 2. The pH can be adjusted by using a buffer solution containing a hydroxyl group (—OH). If the pH of the slurry is more than 5, oxide films such as SiO₂ films are dissolved by —OH group to increase a removing speed of oxide. As a result, the slurry cannot have a high selectivity to nitride.

The content of the strong acid is determined on a basis of a pH value of the slurry. When one strong acid is used, the acid, pH control agent, is present in an amount ranging from about 0.01 to about 20 wt %, preferably from 0.01 to 10 wt % based on the gross weight of the slurry.

If the acid material is present in the amount of less than 0.01 wt % of the gross slurry, a desired pH is not obtained and a chemical reaction due to acid does not occur. If the acid material is present in the amount of more than 20 wt % of the gross slurry, the process tend to be etching rather than CMP due to chemical factor, which deteriorate planarization.

When the pH control agent is a mixture of fluoric acid and nitric acid, a mixture ratio of fluoric acid:nitric acid is in the range of 1:1˜10, preferably 1:1˜3. When the pH control agent is a mixture of fluoric acid and isopropyl alcohol, a mixture ratio of fluoric acid and isopropyl alcohol is in the range of 1:1˜10, preferably 1:1˜3.

In order to decrease a polishing speed of oxide, the disclosed slurry further comprises a surfactant to be selectively adsorbed on oxide. Here, anionic, cationic, amphoteric or nonionic surfactants can be used as the surfactant.

The slurry is used for the CMP or patterning process of nitride film by employing the oxide film as an etching barrier film which is an interlayer insulating film in the Damascene metal gate process or self aligned contact (hereinafter “SAC”) process for forming a capacitor contact. In addition, if the nitride film to be polished is deposited according to a chemical vapor deposition (hereinafter “CVD”) process, the etching selectivity of nitride to the oxide film is increased when the CMP process is performed thereon by using the disclosed slurry.

Specifically, a method using the CMP slurry of the present invention comprises the steps of:

(a) depositing a silicon nitride film on a silicon oxide film pattern; and

(b) performing a CMP process on the silicon nitride film with the silicon oxide film as an etching barrier film by using the slurry of the present invention.

On the other hand, method for manufacturing semiconductor devices using the CMP slurry of the present invention comprises the steps of:

(a) depositing a silicon nitride film on a semiconductor substrate;

(b) depositing a silicon oxide film on the resulting structure;

(c) performing a CMP process on the silicon oxide film with the silicon nitride film as an etching barrier film by using a CMP slurry for oxide film to remove the upper 10% of the target; and

(d) performing a CMP process on the resulting structure by using the CMP slurry for nitride of the present invention to completely remove the silicon oxide film.

The disclosed CMP slurry for nitride will be described in detail by referring to the examples below, which are not intended to be limiting.

### EXAMPLES 1-5

### Preparation of CMP Slurry for Nitride

To 10 L deionized water was added a mixture acid of fluoric acid and nitric acid in a mixture ratio of 1:3 for fluoric acid:nitric acid. The mixture acid was added with 1 wt %, 0.75 wt %, 0.25 wt %, 0.08 wt % and 0.1 wt % of the gross slurry, thereby obtaining a CMP slurry having a pH shown in Table 1.

TABLE 1

| | Example 1 | Example 2 | Example 3 | Example 4 | Example 5 |
|---|---|---|---|---|---|
| pH | pH 1 | pH 2 | pH 3 | pH 4 | pH 5 |

### EXAMPLES 6-12

### Preparation of CMP Slurry for Nitride

Deionized water was added to a CMP slurry containing a 30 wt % colloidal SiO₂ abrasive, thereby obtaining a 10 L CMP slurry containing an abrasive to have a weight content of the gross slurry as shown in Table 2. Here, 1 wt % phosphoric acid was added so that the slurry may have a pH of 2.

TABLE 2

| | Exam- | Exam- | Exam- | Exam- | Exam- | Exam- | Exam- |
|---|---|---|---|---|---|---|---|
| | ple 6 | ple 7 | ple 8 | ple 9 | ple 10 | ple 11 | ple 12 |
| wt % | 24 wt % | 22 wt % | 20 wt % | 18 wt % | 16 wt % | 10 wt % | 5 wt % |

### EXAMPLES 13-20

### Preparation of CMP Slurry for Nitride

Deionized water was added to a CMP slurry containing a 30 wt % colloidal SiO₂ abrasive, then the abrasive was present in an amount of 16 wt % of the gross slurry. Then, a phosphoric acid was added to the resulting solution, thereby obtaining a CMP slurry of Examples 13-20 having a pH as shown in Table 3.

TABLE 3

| | Ex- | Ex- | Ex- | | | | | |
|---|---|---|---|---|---|---|---|---|
| | am- | am- | am- | Exam- | Exam- | Exam- | Exam- | Exam- |
| | ple | ple | ple | ple | ple | ple | ple | ple |
| | 13 | 14 | 15 | 16 | 17 | 18 | 18 | 20 |
| pH | 2.84 | 2.935 | 2.955 | 3 | 3.02 | 3.045 | 3.11 | 3.19 |

### COMPARATIVE EXAMPLES 1˜3

The procedure of Example 6˜12 was repeated to obtain the slurry containing an abrasive by weight of the gross slurry as shown in Table 4 instead of Table 2.

TABLE 4

| | Comparative | Comparative | Comparative |
|---|---|---|---|
| | Example 1 | Example 2 | Example 3 |
| wt % | 30 wt % | 28 wt % | 26 wt % |

### EXPERIMENTAL EXAMPLE 1

### Polishing Selectivity of Nitride Film to Oxide Film by pH Variation (1)

The polishing speed to oxide film and to nitride film was measured, respectively, by using the CMP slurry obtained from Examples 1-5.

Specifically, HDP (High Density Plasma) oxide and LP (Low Pressure) nitride films were polished in CMP equipment by using each slurry obtained from Examples 1-5 at a head pressure of 3 psi and at a table rotation of 70 rpm, thereby measuring the oxide/nitride polishing selectivity.

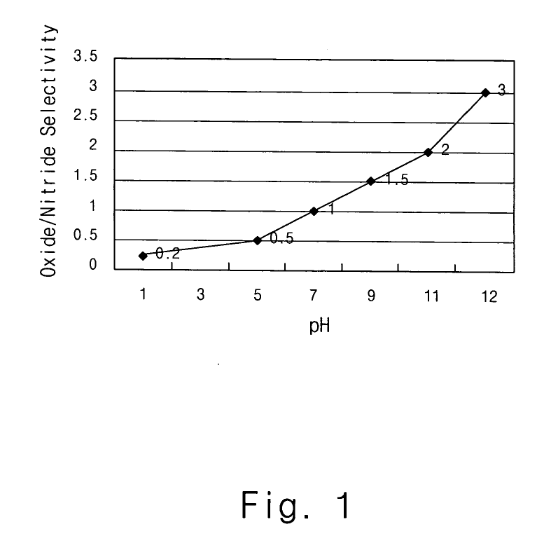

As a result, in a pH of less than about 7, the oxide/nitride polishing selectivity was shown to have less than 1. Moreover, in a pH of less than 5, i.e., when a phosphoric acid was present in an amount of less than 0.1 wt %, the oxide/nitride polishing selectivity was shown to have less than 0.5. The experimental result showed that the nitride was polished twice faster than the oxide by using the CMP slurry of the present invention (see FIG. 1).

### EXPERIMENTAL EXAMPLE 2

### Polishing Selectivity of Nitride Film to Oxide Film by Weight Ratio of Abrasive

The polishing speed to oxide film and to nitride film was measured, respectively, by using the CMP slurry obtained from Examples 6-12 and Comparative Examples 1-3.

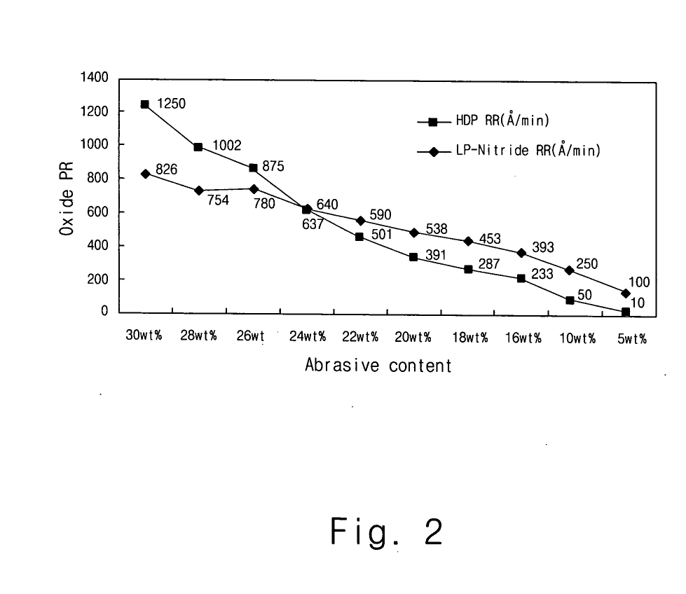

Specifically, HDP oxide and LP nitride films were polished in CMP equipment by using each slurry obtained from Examples 6-12 and Comparative Examples 1-3 at a head pressure of 3 psi and at a table rotation of 70 rpm, thereby measuring the oxide/nitride polishing selectivity (see FIG. 2).

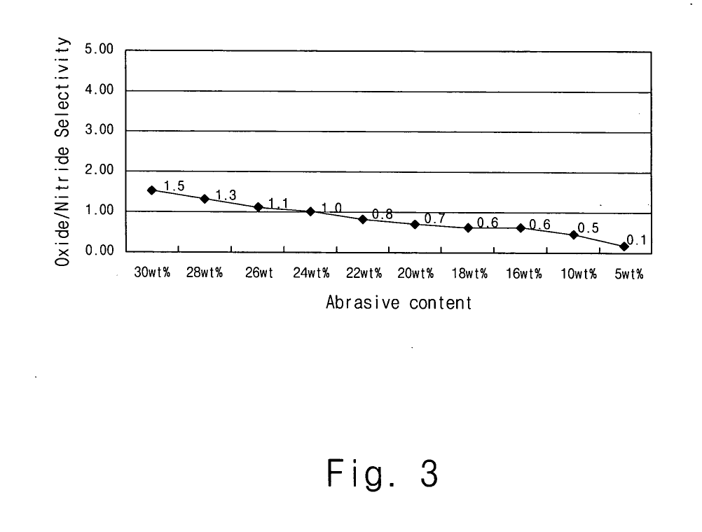

As a result, in a pH of 2 and when the abrasive was present in an amount of less than 24 wt % of the gross slurry, the oxide/nitride polishing selectivity was shown to have less than 1. That is, when the weight ratio of the abrasive was smaller than 24 wt %, the nitride was polished faster than the oxide (see FIG. 3).

### EXPERIMENTAL EXAMPLE 3

### Polishing Selectivity of Nitride Film to Oxide Film by pH Variation (2)

The polishing speed to oxide film and to nitride film was measured, respectively, by using the CMP slurry obtained from Examples 13-20.

Specifically, HDP (High Density Plasma) oxide and LP (Low Pressure) nitride films were polished in CMP equipment by using each slurry obtained from Examples 13-20 at a head pressure of 3 psi and at a table rotation of 70 rpm, thereby measuring the oxide/nitride polishing selectivity.

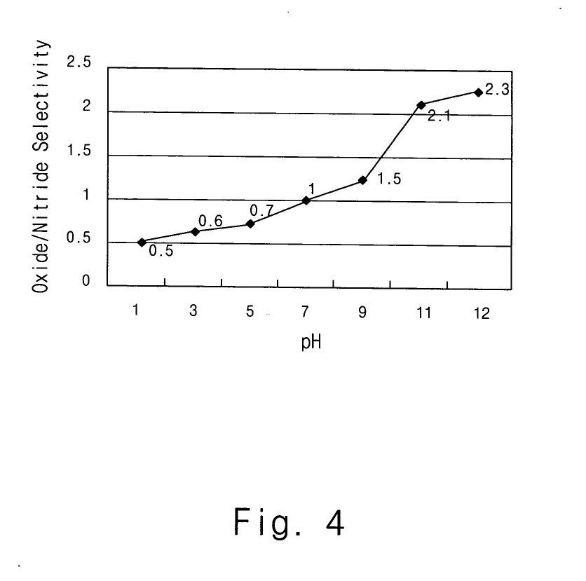

As a result, in a pH of less than 3, i.e., when a phosphoric acid was present in an amount of more than 0.1 wt %, the oxide/nitride polishing selectivity was shown to have less than 1. That is, when the value of the pH was smaller than 3, the nitride was polished faster than the oxide (see FIG. 4).

As described above, the disclosed CMP slurry decreases a polishing speed of oxide by varying a weight ratio of an abrasive and a pH, and increases a polishing speed of nitride, which prevents the oxide from being polishing earlier than the nitride. As a result, semiconductor devices of higher densities and higher integrations can be manufactured.

What is claimed is:

1. A CMP slurry for nitride comprising a pH control agent and having a pH ranging from 1 to 5.

2. The slurry according to claim 1, wherein the pH of the slurry ranges from 1 to 3.

3. The slurry according to claim 2, wherein the pH of the slurry ranges from 1 to 2.

4. The slurry according to claim 1, wherein the pH control agent is selected from the group consisting of phosphoric acid, nitric acid, fluoric acid, mixtures of phosphoric acid and fluoric acid and mixtures of fluoric acid and. isopropyl alcohol.

5. The slurry according to claim 4, wherein the pH control agent is a phosphoric acid.

6. The slurry according to claim 1, further comprising an abrasive in an amount ranging from 0.1 to 24 wt % based on the gross weight of the slurry.

7. The slurry according to claim 1, wherein the abrasive is selected from the group consisting of CeO₂, MnO₂, ZrO₂, Al₂O₃, SiO₂ and mixtures thereof.

8. The slurry according to claim 1, wherein a grain size of the abrasive ranges from 100 nm to 500 nm.

9. The slurry according to claim 1, wherein the abrasive is colloidal and fumed SiO₂.

10. The slurry according to claim 4, wherein the pH control agent is a mixture of fluoric acid and nitric acid in a mixture ratio of 1:1˜10 for fluoric acid nitric acid.

11. The slurry according to claim 10, wherein the mixture ratio of fluoric acid:nitric acid is 1:1˜3.

12. The slurry according to claim 4, wherein the pH control agent is a mixture of fluoric acid and isopropyl alcohol in a mixture ratio of 1:1˜10 for fluoric acid and isopropyl alcohol.

13. The slurry according to claim 12, wherein the mixture ratio of fluoric acid: isopropyl alcohol is 1:1˜3.

14. The slurry according to claim 1, further comprising a surfactant to be selectively adsorbed only on oxide.

15. The slurry according to claim 1, further comprising a buffer solution.

16. A method comprising the steps of:
(a) depositing a silicon nitride film on a silicon oxide film pattern; and
(b) performing a CMP process on the silicon nitride film with the silicon oxide film as an etching barrier film by using the slurry of claim 1.

17. The method according to claim 16, wherein the method is a Damascene process or a SAC process.

18. A semiconductor device manufactured according to the method of claim 16.

19. A method for manufacturing semiconductor devices comprising the steps of:
(a) depositing a silicon nitride film on a semiconductor substrate;
(b) depositing a silicon oxide film on the resulting structure;
(c) performing a CMP process on the silicon oxide film with the silicon nitride film as an etching barrier film by using a CMP slurry for oxide film; and
(d) performing a CMP process on the resulting structure by using the CMP slurry for nitride of claim 1 to completely remove the silicon oxide film.
